(19) United States
(12) Patent Application Publication
(10) Pub. No.: US 2016/0337152 A1
(43) Pub. Date: Nov. 17, 2016

(54) TRANSMITTER, TRANSCEIVER CIRCUIT, AND WIRELESS TRANSMITTING AND RECEIVING SYSTEM

(71) Applicants: FUJITSU LIMITED, Kawasaki-shi (JP); Stichting IMEC, Eindhoven (NL)

(72) Inventors: Shoichi MASUI, Sagamihara (JP); Makoto HAMAMINATO, Kawasaki (JP); Kouichi KANDA, Chofu (JP); Nauman KIYANI, Leuven (BE); Maja VIDOJKOVIC, Leuven (BE); Guido DOLMANS, Leuven (BE)

(21) Appl. No.: 15/224,217

(22) Filed: Jul. 29, 2016

Related U.S. Application Data
(63) Continuation of application No. PCT/JP2014/052464, filed on Feb. 3, 2014.

(51) Int. Cl. H04L 27/20; H04B 1/403; H03L 7/093; H03F 3/24; H03G 1/00; H03L 7/089; H04W 4/00; H04L 12/26

(52) U.S. Cl. CPC H04L 27/2092; H04W 4/005; H04W 4/008; H04B 1/403; H04L 43/028; H03F 3/245; H03G 1/0029; H03L 7/0891; H03L 7/093; H04L 27/2035; H03F 2200/331; H03F 2200/294; H03F 2200/333

(57) ABSTRACT

A transmitter includes a phase control circuit configured to receive a first and a second modulation signals, and a power amplifier configured to receive a third modulation signal. The phase control circuit includes a variable frequency divider, a frequency division ratio being controlled by the first modulation signal; a frequency modulation D/A converter configured to modulate the frequency by the second modulation signal; and a voltage controlled oscillator, including a varactor, configured to receive a first control voltage based on the first modulation signal and a second control voltage based on the second modulation signal. At least one of a capacitance value of the varactor of the voltage controlled oscillator, a control bit number of the frequency modulation D/A converter, and a bias current value of the frequency modulation D/A converter is changed based on a data transfer rate.

### CROSS-REFERENCE TO RELATED APPLICATION

This application is a continuation application and is based upon PCT/JP2014/052464, filed on Feb. 3, 2014, the entire contents of which are incorporated herein by reference.

### FIELD

Embodiments described herein relate to a transmitter, a transceiver circuit, and a wireless transmitting and receiving system.

### BACKGROUND

In recent years, a short-range and low-power radio system realizing a body area network (BAN: Body Area Network) and a sensor network (WSN: Wireless Sensor Networks) have been gaining attention.

Note that, the BAN is a short-range wireless network which realizes data exchanging within a range of about several meters from a human body and its surroundings. By using the BAN, for example, it may be possible to transmit blood pressure, body temperature, bio-information data such as pulse rate and oxygen saturation by using sensors provided on various places of the human body to a data repeater device (hub).

Further, by using the BAN, for example, by providing a plurality number of brain wave (EEG: Electroencephalography) sensor electrodes within a skull of the human body, it may be possible to monitor EEG signal information from the brain wave sensors by wirelessly transmitting to outside of the body.

Furthermore, by using the BAN, for example, it is also possible to transfer image data from a capsule endoscopy medical which is swallowed into the body to a monitor outside the body by wireless transmission. Therefore, by utilizing the BAN, it is possible to realize an advanced medical care.

On the other hand, the WSN is used for collecting information from a plurality of terminals including sensors, and therefore, the WSN may be possible to apply various fields such as a farm or ranch management, a social infrastructure and structures monitoring, factory monitoring, an environmental monitoring, etc.

Note that the short-range wireless standard realizing the above-mentioned BAN and WSN has been proposed, for example, as IEEE802.15.6 and ZigBee (registered trademark). Further, the short-range wireless standard has been also proposed as Bluetooth (registered trademark) Low Energy (BLE) which is a low power version of “Bluetooth (registered trademark)” of the short-range wireless standard.

Note that, the embodiments described later in detail are not limited to apply IEEE802.15.6, ZigBee (registered trademark) and Bluetooth (registered trademark) Low Energy (BLE), but may be widely applied to various types of standards (various specifications).

In a transceiver circuit (transceiver apparatus) that conforms to the short-range wireless standard of IEEE802.15.6 as described above, the maximum data transfer rate of 400 MHz band is, for example, set to 455.4 kbps (402 MHz to 405 MHz band) or 187.5 Kbps (420 MHz to 450 MHz band). Therefore, it is difficult to realize 1 Mbps or more high data transfer rates required for applications such as EEG monitor or image transfer.

Therefore, it is considered to provide a unique high speed mode (high speed data transfer mode), etc. to a wireless communication devise, in addition to a standard mode, so that the user may use the wireless communication device by switching software manner modes.

Incidentally, for example, a node of the wireless sensor embedded in the human body is generally battery powered, and therefore consumption power is reduced as small as possible when an actual biological signal is not sensed.

Therefore, a standby state of a receiver may be set so as to reduce a consumption power of the node, and the consumption power of the node may be increased when transferring data with a high communication performance. Note that, it may be preferable to reduce a data transfer rate so as to realize the standby state of low power consumption, the reasons thereof will be described later in detail.

Further, regarding the node and the hub used for the data repeater (wherein, collected data may be sent to a server provided in, for example, a nurse's station, etc.), characteristics required for transceiver circuits thereof are different each other.

For example, as explained with reference to FIG. 1 in later, in a node transmitting EEG signals, a transmitting circuit (transmitter) which realizes a high speed data transfer is required, and in a hub receiving the EEG signals, a receiving circuit (receiver) which realizes a high speed data receiving is required.

Further, in a node, a capacity of a battery mounted on the node is limited, and thus it is preferable to reduce a standby consumption power of the node. Furthermore, in a hub, it is preferable to include a low speed data transfer mode so as to reduce the receive mode power in the node.

Although different characteristics are required for a node and a hub, however, it is preferable to be implemented on a common hardware of the same semiconductor integrated circuit (transceiver circuit) to the node and the hub by considering a system development and user convenience, etc.

However, it is difficult to realize a transceiver circuit capable of changing a data transfer rate (for example several hundred times), and therefore, it is difficult to realize a node and a hub by applying common hardware.

Conventionally, as wireless communication technology capable of switching between different transmission power modes, various proposals including an integrated circuit design have been proposed.

Patent Document 1: Japanese Unexamined Patent Publication No. 2012-028835

Patent Document 2: Japanese Unexamined Patent Publication No. H10-093475

Patent Document 3: Japanese Unexamined Patent Publication No. 2004-527953

Patent Document 4: Japanese Unexamined Patent Publication No. 2012-142803

Patent Document 5: Japanese Unexamined Patent Publication No. 2002-500490

Patent Document 6: Japanese Unexamined Patent Publication No. 2009-268016

Patent Document 7: International Publication No. 05/083909 pamphlet

Non-Patent Document 1: Yao-Hong Liu et al., “A 2.7nJ/b Multi-Standard 2.3/2.4 GHz Polar Transmitter for Wireless Sensor Networks,” ISSCC Dig. Tech. Papers, pp. 448-449, February 2012.

Non-Patent Document 2: P. Harpe et al., “A 0.7V 7-to-10 bit 0-to-2 MS/s Flexible SAR ADC for Ultra Low power Wireless Sensor Nodes,” IEEE ESSCIRC, pp. 373-376, September 2012.

Non-Patent Document 3: INTERNATIONAL STANDARD, “802.15.6-2012-IEEE Standard for Local and metropolitan area networks-Part 15.6: Wireless Body Area Networks,” February 2012.

### SUMMARY

According to one embodiment, there is provided a transmitter including a phase control circuit configured to receive a first modulation signal from a first path for modulating a first frequency signal, and a second modulation signal from a second path for modulating a second frequency signal higher than the first frequency, and a power amplifier. The power amplifier is configured to receive a third modulation signal from a third path for controlling a gain.

The phase control circuit includes a variable frequency divider, a frequency division ratio being controlled by the first modulation signal, a frequency modulation D/A converter configured to modulate the frequency by the second modulation signal, and a voltage controlled oscillator, including a varactor, configured to receive a first control voltage based on the first modulation signal and a second control voltage based on the second modulation signal.

The transmitter changes at least one of a capacitance value of the varactor (varactor capacitance) of the voltage controlled oscillator, a control bit number of the frequency modulation D/A converter, and a bias current value of the frequency modulation D/A converter based on a data transfer rate.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a block diagram of a wireless transmitting and receiving system, in particular, for explaining a difference of operations required for a node and a hub;

FIG. 2 is a diagram for explaining an example of a specification of an ultra-low power transceiver circuit;

FIG. 3 is a diagram for explaining spreading factors in FIG. 2;

FIG. 4 is a block diagram illustrating a transmitting and receiving device according to the present embodiment;

FIG. 5 is a block diagram illustrating the transceiver circuit in detail illustrated in FIG. 4;

FIG. 6 is a block diagram illustrating an example of a transmitter in the transceiver circuit illustrated in FIG. 5;

FIG. 7 is a diagram for schematically explaining an operation of the transmitter illustrated in FIG. 6;

FIG. 8 is a circuit diagram illustrating a main part of an example of the transmitter according to the present embodiment;

FIG. 9 is an example of a circuit diagram illustrating an extracted frequency modulation D/A converter (FM DAC), a voltage controlled oscillator (VCO), and a frequency divider in the transmitter illustrated in FIG. 8;

FIG. 10 is a diagram for explaining an operation of the transmitter according to the present embodiment;

FIG. 11 is a block diagram illustrating an example of a receiver in the transceiver circuit illustrated in FIG. 5;

FIG. 12 is a circuit diagram illustrating a main part of an example of the receiver according to the present embodiment;

FIG. 13 is a circuit diagram illustrating an extracted low pass filter in the receiver illustrated in FIG. 12;

FIG. 14 is a circuit diagram illustrating an example of a variable power low noise amplifier in the receiver illustrated in FIG. 11;

FIG. 15 is a diagram for explaining an operation of the variable power low noise amplifier illustrated in FIG. 14;

FIG. 16 is a diagram illustrating an example of an attenuator, a matching circuit/switch in the transmitter;

FIG. 17 is a diagram illustrating collectively the control signals in the embodiment described above;

FIG. 18 is a diagram illustrating a standard IEEE802.15.6 compliant PPDU (Physical-layer Protocol Data Unit); and

FIG. 19 is a diagram illustrating a data transfer rate that is set to a rate (RATE) field in IEEE802.15.6 compliant PPDU standard illustrated in FIG. 18.

### DESCRIPTION OF EMBODIMENTS

Hereinafter, embodiments of a transmitter, a transceiver circuit, and a wireless transmitting and receiving system will be described in detail with reference to the attached drawings. In the following description, as an example of a short-range wireless standard that realizes the BAN and WSN, it is described as an example IEEE802.15.6, application of this embodiment is not limited to IEEE802.15.6, ZigBee (registered trademark) or BLE and the like, is also applicable to other wireless systems.

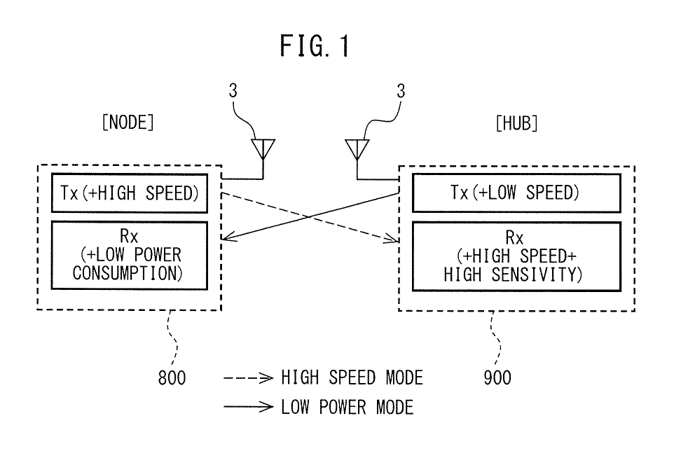

FIG. 1 is a block diagram of a wireless transmitting and receiving system, in particular, for explaining a difference of operations required for a node and a hub, and the wireless transmitting and receiving system includes, for example, at least one node 800, and at least one hub 900.

Data transfer between the node 800 and the hub 900 is carried out by an IEEE802.15.6-compliant mode (compliant mode: a first mode), a high speed data transfer mode (high speed mode: a second mode), and a low speed and low consumption power data transfer mode (low power mode: a third mode) through respective antenna 3.

Each of the node 800 and the hub 900 includes a transceiver circuit including a transmitter (Tx) and a receiver (Rx), as the transceiver circuit (semiconductor integrated circuit) to be applied to the node 800 and the hub 900 may be preferably implemented by a common hardware.

Note that, the high speed mode enables realization of a high speed data transfer of 3.6 Mbps, for example, EEG (Electroencephalogram)/ECG (Electrocardiogram) signals or medical image signals are transferred from the node 800 to the hub 900 at a high speed mode (more than 3 Mbps). The EEG signals means brain wave signals, and the ECG signals means electrocardiographic signals.

Further, in the low power mode, for example, in order to prolong a battery life of the node 800 side, a standby consumption power is minimized at the time of a standby state (Rx: receiving state), where no data is transmitted. In this case, a low speed data transfer mode is set so as to compensate a deterioration of a sensitivity associated with the Rx low power consumption at the time of a TX (transmitting state) of the hub 900.

Incidentally, as described above, in the transmitter conforming to the short-range wireless standard such as IEEE802.15.6, etc., the data rate difference is about 6 times, and thus it is difficult to realize a high data transfer rate required for applications such as EEG monitor or image transferring, and realize of 300 times the data rate transferring speed to cover a low power mode, by a low power consumption.

Therefore, it has been considered for the wireless communication devices to switch among a high speed mode (high speed data transfer mode) and a low power mode in addition to the standard mode by using software.

Note that, when realizing the high speed mode by bundling a plurality of channels, strength of radio wave (electromagnetic wave) radiated from an antenna may be limited based on the Radio Acts passed in various countries. For example, in Japan, the strength of the radio wave is generally limited by the provisions for a weak power radio, and the maximum power to be transmitted from the transmitter may be much smaller than that allowed by IEEE802.15.6 standard.

Therefore, for example, a wireless system (wireless transmitting and receiving system) for 400 MHz and low frequency bands may be attracting attention as a wireless system embedded in a human body, as compared to 2.4 GHz band or 900 MHz band, since an attenuation of wireless power in the human body may be small.

Specifically, a great deal of attention may be attracted to detect and analyze epileptic seizures (epileptic fit) by using a plurality of electrodes onto a surface of a cerebral and taking out measured brain wave signals from the electrodes, and also attracted to recover or assist lost neurological functions by using BMI (Brain-Machine Interface). Note that, when obtaining the measured brain wave signals from the human body, if a wired system is used, an infection may be resulted due to wiring of the wired system for outputting the measured brain wave signals from the human body, and therefore an application of a wireless system may be required.

Note that, for example, 400 MHz band for a medical wireless system includes frequency bands provided for a medical implant communication system (MICS) or a Japanese wireless medical telemetry systems (WMTS) conforming to IEEE802.15.6.

Concretely, for example, the MICS (Medical Implant Communications System) is assigned for 402 MHz to 405 MHz band, and the Japanese WMTS (Wireless Medical Telemetry System) is assigned for 420 MHz to 450 MHz band.

Note that, for example, a data rate of the generally recognized medical signal such as an electrocardiogram signal (ECG), blood pressure signal, a body temperature signal, a pulse signal, and an oxygen saturation signal is less than 100 kbps. Therefore, it is possible to realize the data transfer of the above medical signal by a wireless interface that conforms to IEEE802.15.6.

Incidentally, for example, when realizing the use in analysis of the above described epileptic seizures or the BMI system, a data rate (data transfer rate) of the signals may be required more than 1.5 Mbps, and thus a data rate of the wireless interface is required to 3 Mbps or more.

On the other hand, a node of a wireless sensor embedded in the human body, or placed close to the human body is generally battery powered, and thus, when transmitting no sensing actual biological signal, it is preferable to reduce a consumption power as much as possible.

Therefore, in the node side, it is conceivable to reduce the consumption power by setting the node to a standby state where the node is considered as a receiver for low power consumption, and to increase the consumption power and secure the communication performance by setting the node only for transmitting and receiving data. Note that, in order to achieve the standby state of the low power consumption, it is useful to reduce the data transfer rate.

However, if the wireless interface that conforms to IEEE802.15.6 to greatly change the data transfer rate (compliant mode) for a high speed mode (3.6 Mbps) and a low power (low speed) mode (9.5 kbps), variation of the data transfer rate may be more than 300 times.

Further, in a hub 900 side which receives signals from the node (sensor), different performance is required to the hub 900. Nevertheless, it is preferable to provide a common hardware (transceiver circuit: preferably implemented by applying a semiconductor integrated circuit) for the node and hub, including a wide range of data transfer rates, as described above.

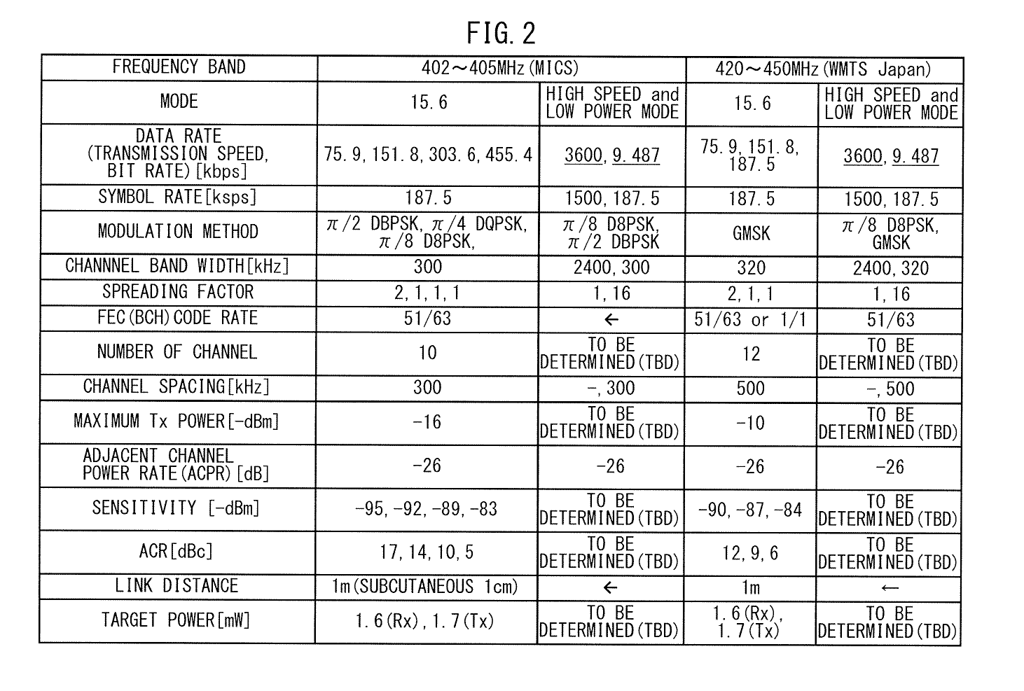

FIG. 2 is a diagram for explaining an example of a specification of an ultra-low power transceiver circuit, for example, a medical implant communication system (MICS) or a Japanese wireless medical telemetry systems (WMTS) conforming to IEEE802.15.6.

As illustrated in FIG. 2, the MICS uses, for example, a frequency band of 402 MHz to 405 MHz, a data transfer rate of the MICS is, for example, defined as 75.9 kbps, 151.8 kbps, 303.6 kbps and 445.4 kbps in a compliant mode (first mode) of IEEE802.15.6 (which is illustrated as 15.6 in FIG. 2).

Further, in the MICS, in this aspect (in respective embodiments which will be described below in detail), the data rate (data transfer rate) is further defined as 3600 kbps (3.6 Mbps: high speed mode (second mode)), and 9.487 kbps (9.5 kbps: low power mode (third mode)).

Furthermore, Japanese WMTS (WMTS Japan) uses, for example, a frequency band of 420 MHz to 450 MHz, and in IEEE802.15.6, the data transfer rate is defined as 151.8 kbps and 187.5 kbps (compliant mode: first mode).

Further, in WMTS, the data rate of the present aspect is defined as 3600 kbps (3.6 Mbps: fast mode: second mode) and 9.487 Kbps (low power mode: third mode).

Note that, in FIG. 2, a reference sign “←” indicates that it is the same as the left side. Further, the high speed mode and the low power mode are not defined in the international standard, and a characteristic such as sensitivity is not specified. Further, a reference sign “-,” in an item of channel spacing indicates the state where no channel spacing exists. For example, when a symbol rate is 3.6 Mbps, it is impossible to set a plurality of channels, and thus there is no channel spacing.

In FIG. 2, the specification illustrated as the present aspect is only an example, for example, the high speed mode of 3.6 Mbps and the low power mode of 9.487 Kbps, the symbol rates of 1500 kbps and 9.487 Kbps, and the modulation methods of π/8 D8PSK, π/2 DBPSK, etc. are merely examples, and various features may be applied.

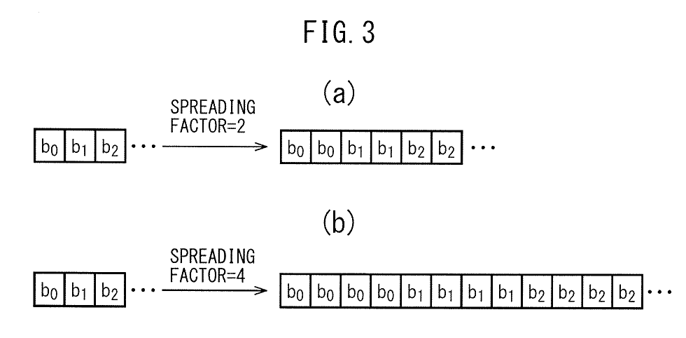

FIG. 3 is a diagram for explaining spreading factors (diffusion coefficient) in FIG. 2. Note that, FIG. 3(a) illustrates the case of the spreading factor=2, and FIG. 3(b) illustrates the case of the spreading factor=4.

In FIG. 2 described above, the spreading factor is set to a value, for example, 1, 2, 16, so as to improve the sensitivity, and the same input bits are repeatedly captured in several times in accordance with the value of the spreading factor.

Specifically, as illustrated in FIG. 3(a), in the case of the spreading factor=2, the input bits b₀, b₁, b₂, . . . are repeatedly captured two times as b₀, b₀, b₁, b₁, b₂, b₂, . . . . Further, as illustrated in FIG. 3(b), in the case of the spreading factor=4, the input bits b₀, b₁, b₂, . . . are repeatedly captured four times as b₀, b₀, b₀, b₀, b₁, b₁, b₁, b₁, b₂, b₂, b₂, b₂, . . . .

Incidentally, the specifications of MICS and WMTS described above are already defined except for the item “the present aspect,” however, the applications of respective embodiments described below are not limited by the specifications of FIG. 2 including the item “present embodiment”.

Specifically, this embodiment is not limited to IEEE802.15.6 of 400 MHz band, and various frequency bands, and ZigBee (registered trademark) or Bluetooth (registered trademark) Low Energy (BLE) and various standards (specifications) may also be applied to other wireless systems.

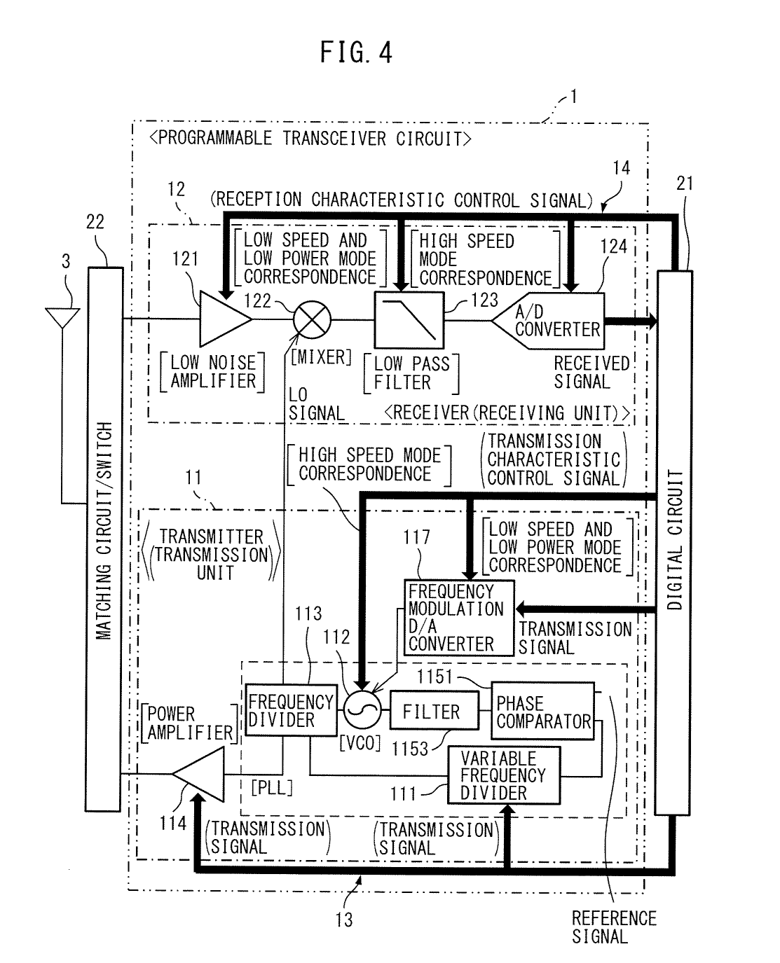

FIG. 4 is a block diagram illustrating a transmitting and receiving device according to the present embodiment. As illustrated in FIG. 4, the transmitting and receiving device of this embodiment includes a transceiver circuit 1, digital circuit 21, matching circuit/switch 22, and antenna 3.

The transceiver circuit 1 includes a transmitter 11 and receiver 12, and a transmitting characteristic control signal 13 and a receiving characteristic control signal 14 are supplied to the transceiver circuit 1 from the digital circuit 21. Note that, the transceiver circuit 1 or the digital circuit 21 (digital baseband circuitry) may be formed as a single semiconductor chip (die). For example, the node 800 and the hub 900 described with reference to FIG. 1 may be realized by applying the transceiver circuit 1 having the same hardware configuration.

The transmitter 11 includes a variable frequency divider 111, a voltage controlled oscillator (VCO) 112, a frequency divider 113, a power amplifier (PA) 114, and a phase frequency detector/charge pump/loop filter unit (PFD/CP/LF) 115.

Note that, the variable frequency divider 111, the VCO 112 and the PFD/CP/LF 115 constitute a phase control circuit (PLL: Phase Locked Loop (circuit)). Further, the PFD/CP/LF 115 indicates all of a phase frequency detector (PFD), a charge pump (CP) and a loop filter (LF).

Specifically, the phase frequency detector PFD receives a clock signal CLK and an output signal of the variable frequency divider 111, and performs a feedback control of the VCO 112 via the charge pump CP and the loop filter LF, so that the clock signal CLK and the output signal of the variable frequency divider 111 are synchronized.

The receiver 12 includes a low noise amplifier (LNA) 121, a mixer 122, a low pass filter 123, and an A/D converter (ADC: Analog-to-Digital Converter) 124.

The digital circuit 21 receives a demodulated signal from the receiver 12 and performs a receiving process, and controls the receiver 12 by the receiving characteristic control signal 14. Further, the digital circuit 21 controls the transmitter 11 by the transmitting characteristic control signal 13.

Note that, the transmitting characteristic control signal 13 includes a low frequency phase modulation signal S_{LP} for the variable frequency divider 111, a high frequency modulation signal S_{HP} for the VCO 112 via a frequency modulation D/A converter, and a modulated signal S_{PA} for the PA 114.

The matching circuit/switch 22 matches (performs matching) between the antenna 13 and the transmitter 11 or the receiver 12, and also controls the connection between the antenna 13 and the transmitter 11 or the receiver 12 in accordance with the operation of a transmission (Tx) or a reception (Rx).

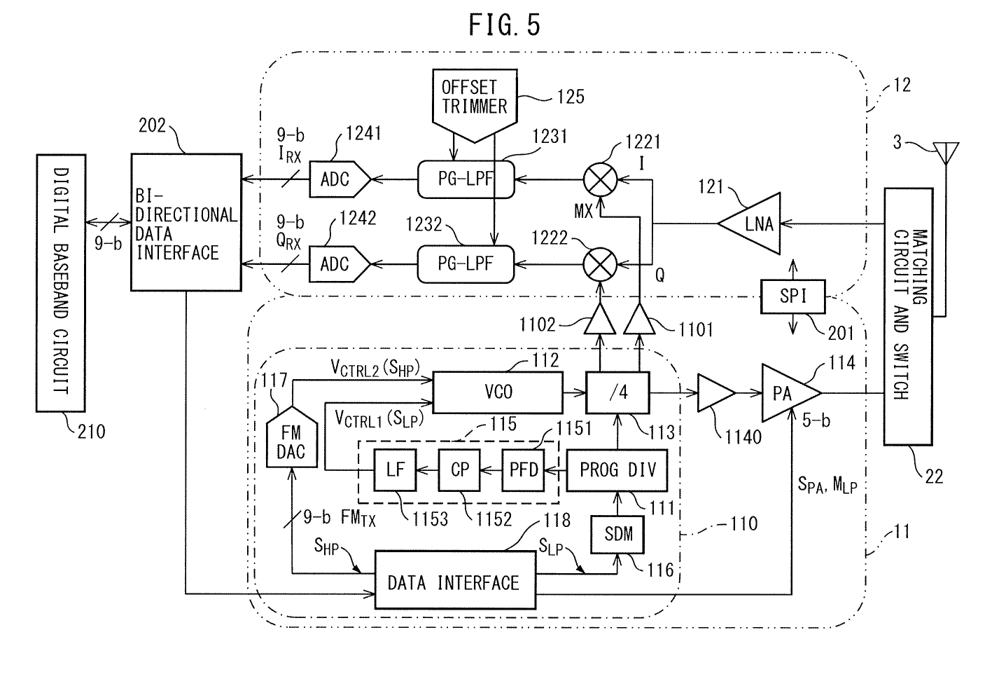

FIG. 5 is a block diagram illustrating the transceiver circuit in detail illustrated in FIG. 4. As is apparent from a comparison of FIG. 5 with FIG. 4 described above, in FIG. 5, the matching circuit/switch 22 and the antenna 3 are illustrated in a right side which is opposite side of FIG. 4.

Note that, in FIG. 5, the transmitter 11 adopts a three-point modulation method, and is formed as a polar modulation type transmitter including PLL (Phase Locked Loop) circuits 111, 112, 113, 115 and a direct modulation PA 114. Further, in FIG. 5, a programmable divider (PROG DIV) 111 corresponds to the variable frequency divider 111 illustrated in FIG. 4.

Furthermore, in FIG. 5, the receiver 12 is formed as a zero IF (zero Intermediate Frequency) type programmable receiver. Note that, the mixer 122 and the ADC 124 illustrated in FIG. 4 correspond to two mixers 1221 and 1222, two programmable LPFs (PG-LPF) 1231 and 1232, and two ADCs 1241 and 1242 for orthogonal I and Q phases, respectively. Note that, a DC offset caused by the receiver is compensated by an offset trimmer 125 which is connected to the programmable LPF.

In FIG. 5, a serial peripheral interface (SPI) 201 and a bi-directional data interface 202 are, for example, used to transmit and receive data and signals between the transceiver circuit and the digital baseband circuit 210. Note that, the SPI 201 is, for example, a 1-bit serial interface, and the bi-directional data interface 202 is, for example, a 9-bit parallel interface.

Further, the transmitter 11 includes a data interface 118 for receiving data from the bi-directional data interface 202, and a frequency modulation D/A converter (FM DAC) 117 for frequency modulation D/A converting an FM transmission signal from the data interface 118. Note that, the FM transmission signal of 9 bits (9-b FM_{TX}) output from the data interface 118 corresponds to the high frequency modulation signal S_{HP} from the high frequency modulation path.

The programmable divider 111 is controlled by an output of a sigma-delta modulator (SDM) 116 which receives an output signal of the data interface 118. Note that the output from the data interface 118 to SDM 116 corresponds to the low frequency phase modulation signal S_{LP} from the low frequency modulation path.

In FIG. 5, a power amplifier buffer (PA buffer) 1140 is provided at a previous stage of the PA 114, and an output of the frequency divider 113 is input into the mixers 1221 and 1222 via buffers (e.g., 25% duty ratio LO (Local Oscillator) buffers) 1101 and 1102.

In the PFD/CP/LF 115, a PFD 1151 receives an output of the programmable divider 111, and outputs a first control voltage V_{CTRL1} to the LC-VCO (LC type voltage controlled oscillator) 112 via a CP 1152 and an LF 1153. Further, the FM DAC 117 receives an FM transmission signal (9-b FM_{TX}) from the data interface 118, and outputs a second control voltage V_{CTRL2} to the VCO 112.

Note that, the programmable divider 111, the VCO 112, the frequency divider 113, the PFD/CP/LF 115, the SDM 116, the FM ADC 117 and the data interface 118 constitute a fractional-N type PLL circuit 110.

Therefore, the VCO 112 receives the low frequency phase modulation signal S_{LP} from the low frequency modulation path which is eventually the first control voltage V_{CTRL1}, and the high frequency modulation signal S_{HP} from the high frequency modulation path which is eventually the second control voltage V_{CTRL2}.

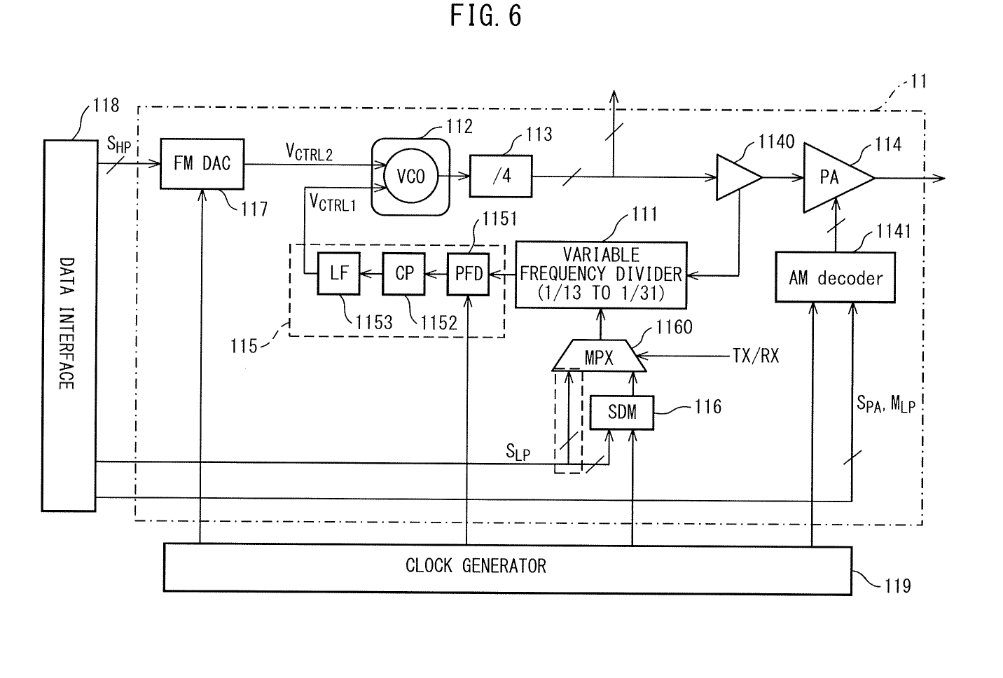

FIG. 6 is a block diagram illustrating an example of a transmitter in the transceiver circuit illustrated in FIG. 5. In FIG. 6, the blocks denoted by the same reference numerals as in FIG. 5 illustrate the similar features thereof. As illustrated in FIG. 6, a clock generator 119 generates a clock signal based on a clock of 24 MHz and output the clock signal to a PFD 1151 and SDM 116. Note that the clock signal from the clock generator 119 may be supplied to various other circuits.

The high frequency phase modulation signal S_{HP} (e.g., 9-bit FM transmission signal 9-b FM_{TX}) from the data interface 118 is converted frequency modulated D/A by the FM DAC 117 to the second control voltage V_{CTRL2}, and the second control voltage V_{CTRL2} is output to the LC-VCO 112 of which reference oscillation frequency is, for example, 1.6 GHz.

Note that the output of the VCO 112 is, for example, divided to ¼ frequency by the frequency divider 113. An output of the frequency divider 113 is input to the PA 114 via the PA buffer 1140, and also input to the variable frequency divider 111, so that a feedback control is carried out via the PFD 1151, the CP 1152, and the LF 1153 (PFD/CP/LF 115). The output of the frequency divider 113 is also applied to the mixer 122 (1221, 1222) of the receiver 12.

Further, the low frequency modulation signal SLP (for example, fractional part 14 bits in 19-bit signal) from the data interface 118 is sigma-delta modulated by the SDM 116 and input to a multiplexer (MPX) 1160.

Note that, for example, it is possible to input integer part five bits in 19-bit signal to the MPX 1160, and wherein one of input signals of the MPX 1160 is selected by a switching control signal TX/RX of the transceiver circuit and input to the variable frequency divider 111.

Incidentally, the variable frequency divider 111 is, for example, set to 1/13 frequency division to 1/31 frequency division, and a division rate is controlled by five bits signal output from the MPX 1160. Further, the low frequency phase modulation signal SLP from the data interface 118 is input to the VCO 112 as the first control voltage V_{CTRL1} via the SDM 116, the MPX 1160, the variable frequency divider 111 and the PFD/CP/LF 115.

An AM decoder (amplitude modulation decoder) 1141 receives a signal M_{LP}. for switching a mode from the data interface 118 to the PA 114 and a modulation signal (third modulation signal) S_{PA} for controlling a gain of the PA 114, and modulation controls the PA 114.

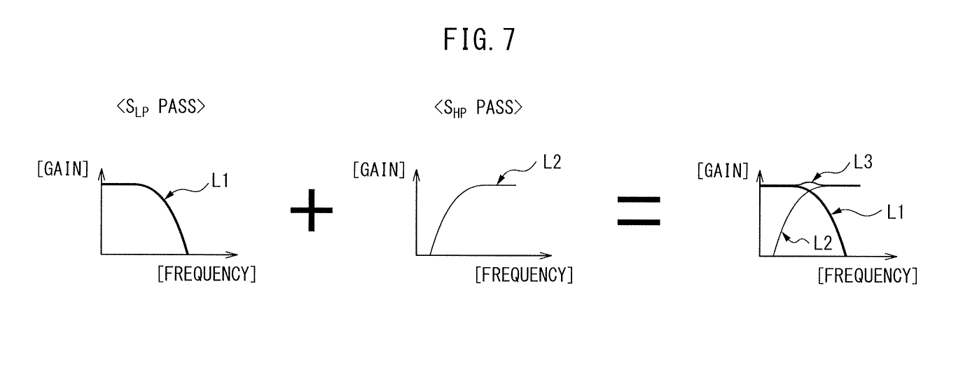

FIG. 7 is a diagram for schematically explaining an operation of the transmitter 11 illustrated in FIG. 6. As illustrated in FIG. 7, according to the transmitter of the present embodiment, a characteristic curve L3 is obtained by adding a characteristic curve L1 caused by the low frequency phase modulation signal S_{LP} from the low frequency modulation path and a characteristic curve L2 caused by the high frequency modulation signal S_{HP} from the high frequency modulation path, so that the characteristic curve L3 includes a sufficient gain in a wide frequency band. Note that a transmitter based on only the low frequency phase modulation signal S_{LP} may be provided, however, it is difficult to realize an unusual high data rate.

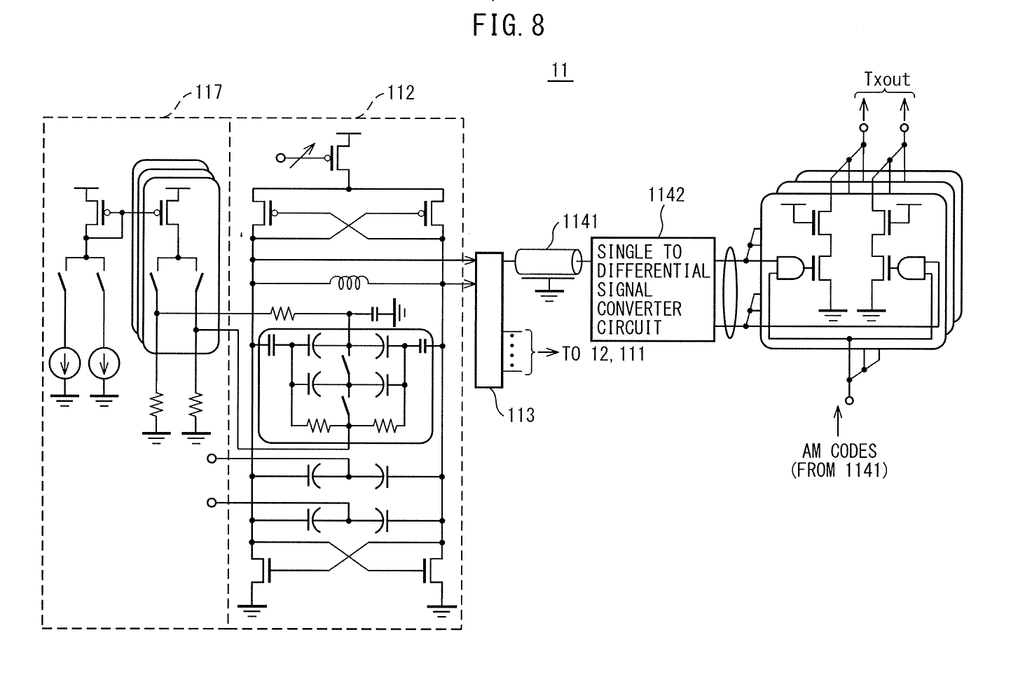

FIG. 8 is a circuit diagram illustrating a main part of an example of the transmitter according to the present embodiment, and more specifically, indicates an example of a configuration from the FM DAC (frequency modulation D/A converter) 117 to the PA (power amplifier) 114. Note that, reference numeral 1141 denotes a wiring load capacitor on an integrated circuit, and 1142 denotes a single to differential signal converter circuit.

Note that, in the transmitter 11 illustrated in FIG. 8, the PA 114 receives differential signals from the single to differential converter circuit 1142, and outputs modulated and amplified differential transmission signals TXout based on AM codes from an AM decoder 1141. Note that the transmission signals TXout are transmitted to the antenna 3 via the matching circuit/switch 22.

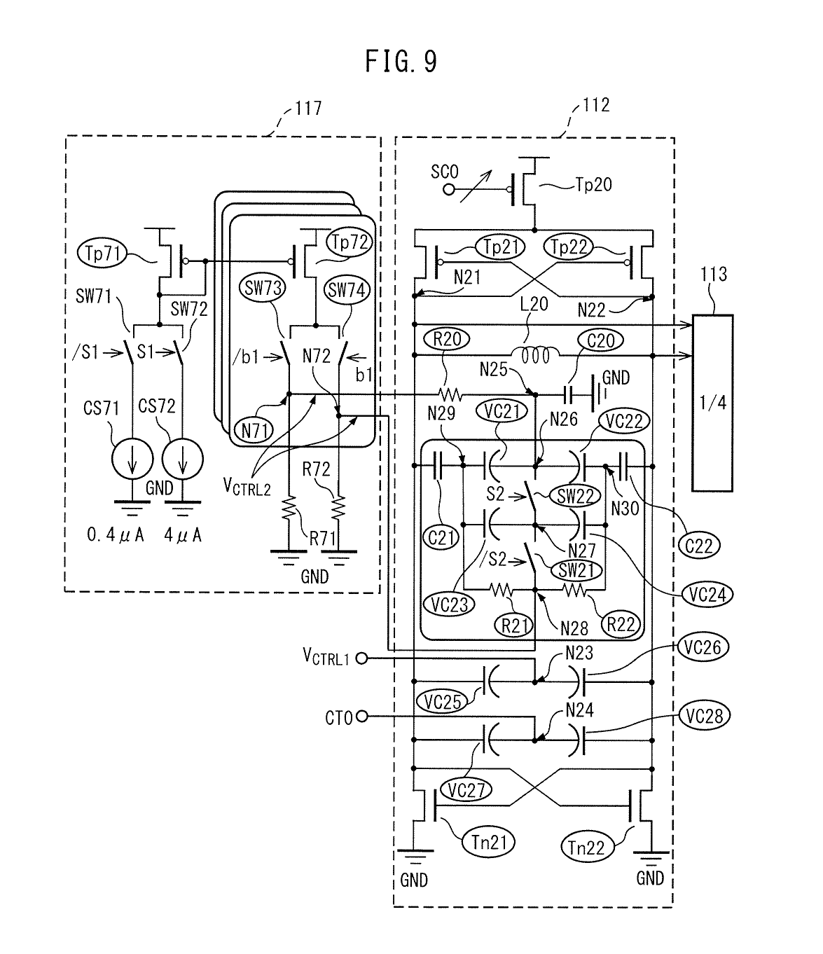

FIG. 9 is an example of a circuit diagram illustrating an extracted frequency modulation D/A converter (FM DAC) 117, a voltage controlled oscillator (VCO) 112, and a frequency divider 113 in the transmitter illustrated in FIG. 8.

Note that, the FM DAC 117 is formed as a 9-bit current differential DAC, the VCO 112 is formed as an LC type voltage controlled oscillator (LC VCO). Note that, regarding signals for controlling respective switches, for example, a signal/S1 denotes an inverted signal of a signal S1.

As illustrated in FIG. 9, the FM DAC 117 includes p-channel type MOS transistors (pMOS transistors) Tp71, Tp72, switches SW71 to SW74, current sources CS71, CS72, and resistors R71, R72. Each of the switches SW71 to SW74 is constituted by a pMOS or nMOS transistor or both transistors (transfer gate formed by nMOS and pMOS transistors).

Note that, a unit formed by the transistors Tp72 and the switches SW73, SW74 is provided a plurality (e.g., nine units). Further, the transistor Tp72 of each unit is connected as a current mirror connection with a transistor Tp71, and thus a current (0.4 μA or 4 μA) flowing through the transistor Tp71, which is switched by the switches SW71, SW72, is transferred to the transistor Tp72.

Specifically, when a switch control signal S1 is at “1”, i.e., when a signal/S1 is at “0”, the switch SW72 is turned on and the switch SW71 is turned off, a current of 4 μA flows in the transistor Tp71. As a result, a current proportional to 4 μA flows in the transistor Tp72 which is connected to the transistor Tp71 as the current mirror connection.

Conversely, when the switch control signal S1 is at “0” (/S1 is at “1”), the switch (which is used for switching a DAC bias voltage) SW72 is turned off and the switch SW71 is turned on, a current of 0.4 μA of a current power source CS71 flows in the transistor Tp71. As a result, a current proportional to 0.4 μA flows in the transistor Tp72 which is connected to the transistor Tp71 as the current mirror connection. Specifically, when the switch control signal S1 is at “0,” 1/10 current of the current at the time of S1 is at “1” flows in the transistor Tp72.

In each unit, the switch SW73 is on/off controlled by a switch control signal (each bit) bi based on the high frequency modulation signal S_{HP}, and similarly, the switch SW74 is on/off controlled by a switch control signal/b1.

In the above descriptions, the differential second control voltage V_{CTRL2} is generated based on the FM transmission signal 9-b FM_{TX} output from the data interface 118, and therefore, it may be considered that the differential second control voltage V_{CTRL2} is generated based on the high frequency phase modulation signal S_{HP}.

Specifically, for example, when setting the transmitter 11 as a low power mode of which data rate is 9.5 kbps (9.487 kbps), the signal S1 is set to “0” so as to reduce the current (0.4 μA) flowing through the transistor Tp72. Further, when setting the transmitter 11 as a high speed mode of which data rate is 3600 kbps, the signal S1 is set to “1” so as to increase the current (4 μA) flowing through the transistor Tp72.

Further, a control bit number of the FM DAC 117 may be controlled by the mode of setting the transmitter 11. For example, when setting the transmitter 11 to the low power mode of 9.5 kbps data rate, the control bit number is decreased to 7 bits, and when setting the transmitter 11 to the high speed mode of 3600 kbps data rate, the control bit number is increased to 9 bits (more than the time of the low power mode).

Next, as illustrated in FIG. 9, the VCO 112 includes pMOS transistors Tp20 to Tp22, nMOS transistors Tn21, Tn22, switches (varactor changeover switches) SW21, SW22, and an inductor (coil) L20.

Further, the VCO 112 includes capacitors C20 to C22, resistors R20 to R22, and varactors (which are also called as varactor diodes, variable capacitance diodes, or varicap diodes) VC21 to VC28.

Note that, gates and drains of the transistors Tp21 and Tp22 are cross connected each other, and gates and drains of the transistors Tn21 and Tn22 are also cross connected to each other.

Sources of the transistors Tp21 and Tp22 are commonly connected to a drain of the transistor Tp20, and a source of the transistor Tp20 is connected to a high potential power supply line. Further, sources of the transistors Tn21 and Tn22 are connected to the ground.

The inductor L20 is connected between a connection node N21 of connecting the drain of the transistor Tp21 and the drain of the transistor Tn21, and a connection node N22 of connecting the drain of the transistor Tn22 and the drain of the transistor Tp22.

Further, between the connection node N21 and the connection node N22: the varactors VC25 and VC26 are connected in series; the varactors VC27 and VC28 are connected in series; and the capacitor C21, the varactors VC21 and VC22 and the capacitor C22 are connected in series.

In addition, between a connection node N29 of connecting the capacitor C21 and the varactor VC21, and a connection node N30 of connecting the varactor VC22 and the capacitors C22: the varactors VC23 and VC24 are connected in series, and the resistors R21 and R22 are connected in series.

Note that, the first control voltage V_{CTRL1} described above is applied to a connection node N23 of connecting the varactors VC25 and VC26, and a signal CTO used for performing coarse adjustment of the oscillation frequency is input to a connection node N24 of connecting the varactors VC27 and VC28.

Further, a switch SW21, which is on/off controlled by a switch control signal/S2, is provided between a connection node N28 of connecting the resistors R21 and R22, and a connection node N27 of connecting the varactors VC23 and VC24.

In addition, a switch SW22, which is on/off controlled by a switch control signal S2, is provided between a connection node N26 of connecting the varactors VC21 and VC22, and the connection node N27 of connecting the varactors VC23 and VC24.

A connection node N71 of the FM DAC 117 described above is connected to one end of the resistor R20, the other end (connection node N 25) of the resistor R20 is connected to one end of the capacitor C20, and the other end of the capacitor C20 is connected to the ground.

Further, a connection node N72 of the FM DAC 117 is connected to the connection node N28 of connecting the resistors R21 and R22. Therefore, the second control voltage V_{CTRL2} generated by the FM DAC 117 is input to the VCO 112.

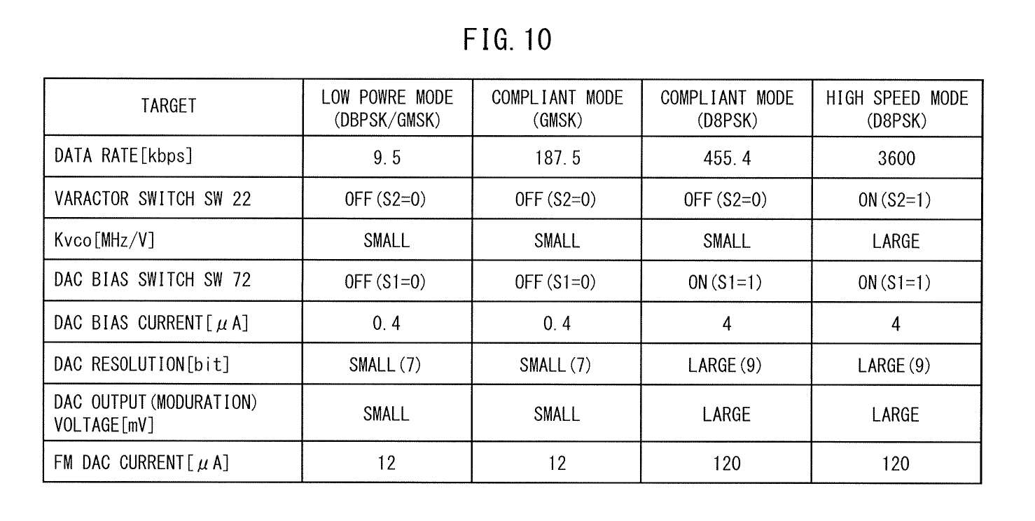

FIG. 10 is a diagram for explaining an operation of the transmitter according to the present embodiment, as an example, data transfer rate of 455.4 kbps in WMTS and data rate of 187.5 kbps in MICS conforming to IEEE802.15.6, and for illustrating a low power mode and a high speed mode of the present embodiment. In FIG. 10, the data transfer rate (data rate) of the low power mode of 9.487 kbps is illustrated as 9.5 kbps.

As illustrated in FIG. 10, for example, when setting the transmitter 11 to the low power mode (DBPSK/GMSK), the signal S1 is set to “0” so as to turn off the DAC bias changeover switch SW72 and turn on the DAC bias changeover switch SW71, and reduce a bias current (current flowing through the transistor 72) to 0.4 μA.

Further, for example, when setting the transmitter 11 to the low power mode, the signal S2 is set to “0” so as to turn off the varactor changeover switch SW22 and turn on varactor changeover switch SW21, and reduce a capacitance value of the connection node N26 at a capacitance value formed by the varactors VC21 and VC22.

In addition, for example, when setting the transmitter 11 to the low power mode, the control bit number of the FM DAC 117 is decreased to 7 bits, or a resolution of the DAC is reduced.

On the other hand, for example, when setting the transmitter 11 to the high speed mode (D8PSK), the signal S1 is set to “1” so as to turn on the DAC bias changeover switch SW72 and turn off the DAC bias changeover switch SW71, and increase the bias current to 4 μA.

Further, for example, when setting the transmitter 11 to the high speed mode, the signal S2 is set to “1” so as to turn on the varactor changeover switch SW22 and turn off varactor changeover switch SW21, and increase the capacitance value of the connection node N26 at a capacitance value formed by the varactors VC21, VC23, VC22 and VC24.

In addition, for example, when setting the transmitter 11 to the high speed mode, the control bit number of the FM DAC 117 is increased to 9 bits, or the resolution of the DAC is increased.

Note that, the above three techniques are independently performed, and further the above three techniques may be performed with preferably combining, so that a synergistic effect of a wide range of data rate may be expected.

Next, an effect of switching varactors, and an effect of switching DAC bias currents and DAC resolutions will be explained. For example, when the switch SW22 is turned off (wherein a varactor capacitance is small), a gain K_{VCO} of the VCO 112 is small, and when the switch SW22 is turned on (wherein the varactor capacitance is large), the gain K_{VCO} of the VCO 112 is large.

Further, when the switch SW72 is turned off (wherein the bias current is small) and a DAC resolution is small (7 bits), a DAC output (modulated) voltage is small, and when the switch SW72 is turned on (wherein the bias current is large) and the DAC resolution is large (9 bits), the DAC output voltage is large.

Note that, by turning on the switch SW 22, the varactor capacitance is increased, the gain K_{VCO} of the VCO 112 is increased, and a change of the frequency with respect to variation of a modulation signal voltage is increased, so that a high data transfer rate may be possible.

Nevertheless, by using the same configuration for a low data transfer rate, it is required to decrease the modulation signal (second control voltage) V_{CTRL2}, and a quantization noise may be caused in the high frequency modulation signal S_{HP}, since the high frequency modulation signal is a digital signal. Therefore, it is preferable to turn off the switch SW22 and use the transmitter in the state where the gain K_{VCO} of the VCO 112 is reduced, except for the high speed mode.

Further, as illustrated in FIG. 10, in the high speed mode and the compliant mode of a D8PSK modulation which is relatively high transfer data rate, control bit number of the FM DAC 117 is set to 9 bits (large: more), and further the bias current is also increased.

On the other hand, in the low power mode and the compliant mode of a GMSK modulation which is relatively low data transfer rate, control bit number of the FM DAC 117 is set to 7 bits (small: less), and further the bias current is also decreased. Therefore, by changing the output (modulation) voltage of the FM DAC 117, the second control voltage V_{CTRL2} may be optimized in accordance with the data transfer rate.

Specifically, for example, when the data transfer rate is at a low power mode of 9.5 Kbps or at a high speed mode of 3600 kbps, where the data transfer rate is different 300 times or more, a suitable data transmission (transmission and reception) may be possible without increasing the DAC resolution (the number of required bits), that is, without increasing a consumption power. Further, according to the present embodiment, by lowering the output (modulation) voltage of the FM DAC 117, an effect of decreasing power consumption may be obtained.

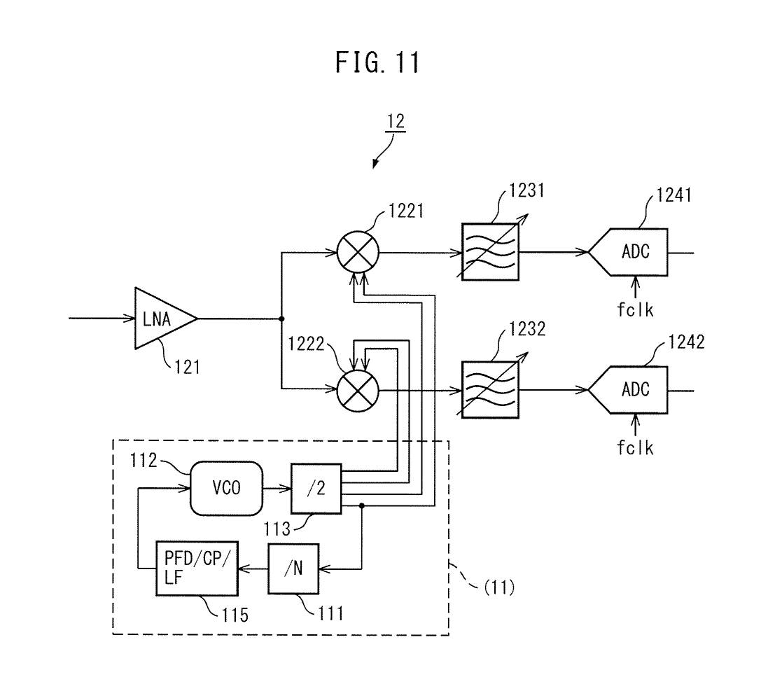

FIG. 11 is a block diagram illustrating an example of a receiver in the transceiver circuit illustrated in FIG. 5, wherein a low noise amplifier 121, mixers 1221 and 1222, low pass filters 1231 and 1232, and ADCs 1241 and 1242 are illustrated with a PLL (including a variable frequency divider 111, a VCO 112, a divider 113, and a PFD/CP/LF 115) of the transmitter 11.

Note that the low noise amplifier (LNA) 121 is formed as a variable power low noise amplifier capable of variably controlling a power based on a compliant mode, a high speed mode and a low power mode described above.

Further, the LPFs 1231 and 1232 are formed as variable gain and variable cut-off frequency type low pass filters capable of variably controlling a cut-off frequency based on the compliant mode, the high speed mode and the low power mode.

Furthermore, the ADCs 1241 and 1242 are formed as variable sampling clock A/D converters capable of variably controlling a sampling frequency (clock frequency fclk) based on the compliant mode, the high speed mode and the low power mode.

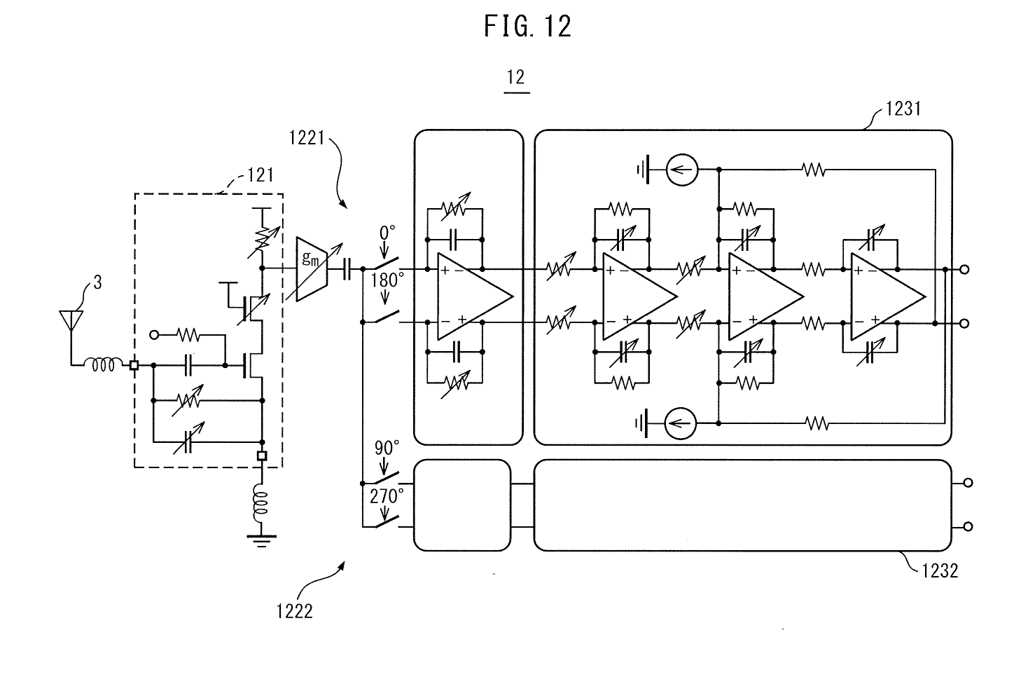

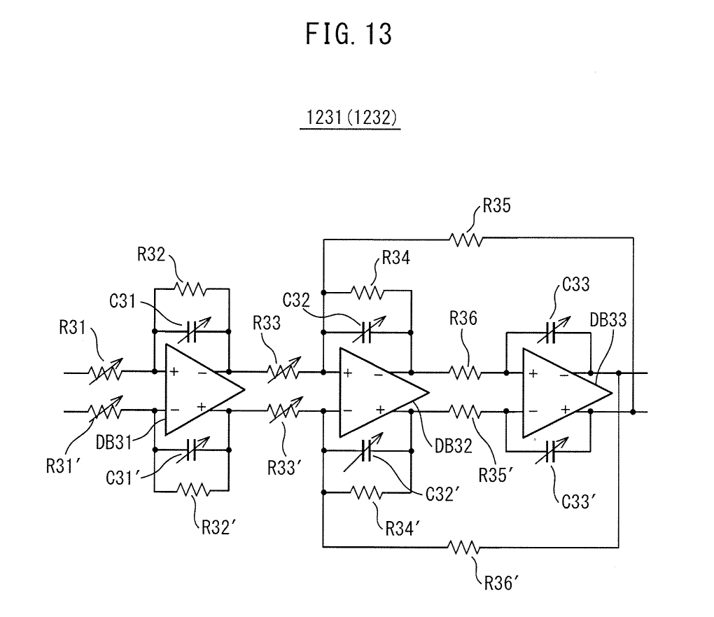

FIG. 12 is a circuit diagram illustrating a main part of an example of the receiver according to the present embodiment, wherein the LNA 121, the mixers 1221 and 1222, the low pass filters 1231 and 1232, are illustrated with an antenna 3. Further, FIG. 13 is a circuit diagram illustrating a low pass filter 1231 (1232) in the receiver illustrated in FIG. 12, i.e., a circuit diagram illustrating an example of the variable gain and variable cut-off frequency type low pass filter illustrated in FIG. 11.

The variable gain and variable cut-off frequency type low pass filter 1231 is formed as a differential configuration and includes a plurality of resistors R31 to R36, R31′ to R36′, capacitors C31 to C33, C31′ to C33′, and operational amplifiers DB31 to DB33.

Note that, by adjusting capacitance values of the capacitors C31 to C33 (C31′ to C33′), it is possible to vary the cut-off frequency, and further, by adjusting resistance ratios of R32/R31 (R32′/R31′), and R35/R33 (R35′/R33′), it is possible to vary the gain.

Specifically, for example, so as to respond to a data transfer rate, in the high speed mode, the cut-off frequency of the low pass filter 1231 is set to high, and in the compliant mode and the low power mode, the cut-off frequency of the low pass filter 1231 is set to low.

Although it is not illustrated in FIG. 13, as described with reference to FIG. 11, that the clock frequency fclk of the ADCs 1241 and 1242 may be changed in accordance with the compliant mode, the high speed mode and the low power mode.

Specifically, in the low power mode and the compliant mode, the clock frequency fclk is set to a low speed (for example, 1.5 MHz), and in the high speed mode, the clock frequency fclk is set to a high speed (for example, 12 MHz). Note that the technique disclosed in Non-Patent Document 2 may be applied so as to vary the clock frequency (sampling frequency of the ADC).

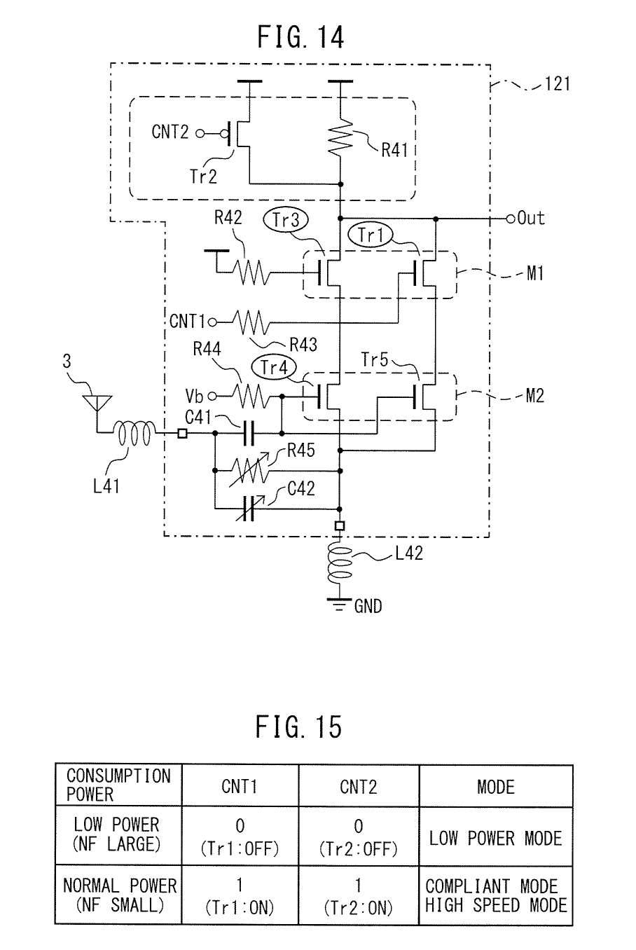

FIG. 14 is a circuit diagram illustrating an example of a variable power low noise amplifier in the receiver illustrated in FIG. 11, and FIG. 15 is a diagram for explaining an operation of the variable power low noise amplifier illustrated in FIG. 14.

As illustrated in FIG. 14, the variable power low noise amplifier 121 includes a pMOS transistor Tr2, nMOS transistors Tr1 and Tr3 to TrS, resistors R41 to R45, capacitors C41 and C42, and inductors L41 and L42. Note that the resistor R45 is a variable resistor, and the capacitor C42 is a variable capacitor.

One end of the resistor R41 is connected to a high potential power supply line, and the other end of the resistor R41 is connected to a drain of the transistor Tr2 and an output signal Out is output therefrom. Specifically, the transistor Tr2 is connected in parallel with the resistor R41, and a control signal CNT2 is input to a gate of the transistor Tr2.

The resistor R41, the transistors Tr3 and Tr4, and an inductor L42 are connected in series between the high potential power supply line and the ground, wherein a gate of the transistor Tr3 is connected to the high potential power supply line via the resistor R42.

A predetermined bias voltage Vb is applied to a gate of the transistor Tr4 via the resistor R44. The gate of the transistor Tr4 is connected to a gate of the transistor Tr5 and one end of the capacitor C41, and the other end of the capacitor C41 is connected to the antenna 3 via the inductor L41 and commonly connected to one ends of the variable resistor R45 and the variable capacitor C42.

The other ends of the variable resistor R45 and the variable capacitor C42 are commonly connected to sources of the transistors Tr4 and Tr5. A connection node (Out) between the other end of the resistor R41 and a drain of the transistor Tr2 is connected to a drain of the transistor Tr1, and a source of the transistor Tr1 is connected to a drain of the transistor Tr5.

Note that the control signal CNT1 is input to a gate of the transistor Tr1 via the resistor R44. Further, the inductors L41 and L42 are, for example, provided within a semiconductor chip where the LNA 121 (transmitter 11 or transceiver circuit 1) is formed or outside of the semiconductor chip, depending on an operating frequency band.

As illustrated in FIG. 15, in the low power mode, the transistors Tr1 and Tr2 are turned off by setting the control signals CNT1 and CNT2 to “0”. Specifically, the control signal CNT1 is set to a low level, the nMOS transistor Tr1 is turned off, and a path between the transistors Tr1 and Tr5 connected in series is cut-off.

Therefore, a received signal input through the antenna 3 and the inductor L41 is amplified by a single transistor Tr4 (one Gm element). Note that, the pMOS transistor Tr2 is turned off by setting the control signal CNT2 to a high level, and a current only flows in the resistor R41, so that a consumption power may be reduced.

According to the present embodiment, in the low power mode, a noise figure (NF) is large, but the consumption power may be reduced (large NF, and low consumption power). Note that, with respect to sensitivity reduction due to the NF becomes large, it is possible to compensate by setting the spreading factor described with reference to FIG. 3 to two or more.

Specifically, when using the spreading factor of two, it is possible to improve a reception sensitivity with 3 dB, and when using the spreading factor of sixteen, it is possible to improve the reception sensitivity with 12 dB, so that a deterioration of the reception sensitivity caused by increasing the NF may be compensated.

Further, as another method, the sensitivity may be improved with 10 dB by reducing an order of magnitude usage band, or applying various methods, a wireless transmitting and receiving system wherein a communication distance does not change even in the low power mode may be constructed.

On the other hand, in the compliant mode and the high speed mode, the transistors Tr1 and Tr2 are turned on by setting the control signals CNT1 and CNT2 to “1”. Specifically, the control signal CNT1 is set to a high level, the nMOS transistor Tr1 is turned on, and a received signal is amplified by two transistors Tr1 and Tr3.

Further, the control signal CNT2 is set to a low level, the pMOS transistor Tr2 is turned on, and thus a current flows in the resistor R41 and the transistor Tr2. Therefore, in the compliant mode and the high speed mode, even though the power is normal, but the noise figure may be small (normal power, small NF).

For example, as described with reference to FIG. 1, it is applicable to a variable power low noise amplifier (LNA) 121 used for the transceiver circuit of the receiving side in a wireless transmitting and receiving system including at least one node 800 and at least one hub 900.

Specifically, at the node 800 and the hub 900, when the power for amplifying a received signal by the LNA 121 of the receiving side is reduced (low power mode), by setting a spreading factor to two or more, a sensitivity reduction may be compensated. Further, by reducing the operating band, the sensitivity reduction may be also compensated.

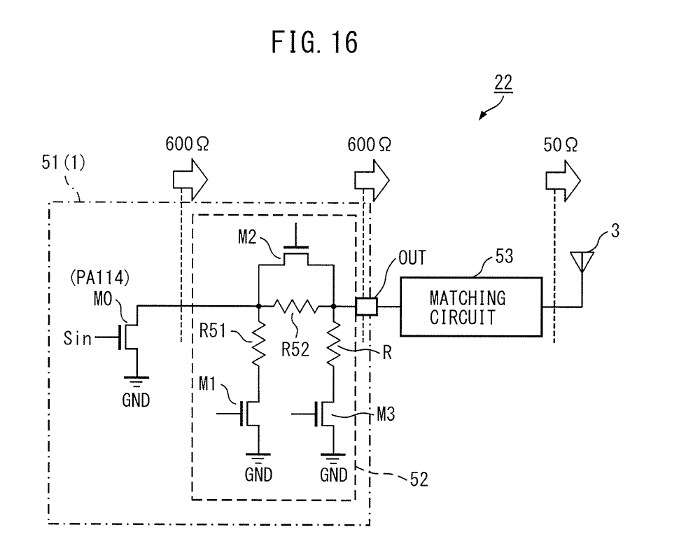

FIG. 16 is a diagram illustrating an example of an attenuator, a matching circuit/switch in the transmitter. Note that, reference 51 denotes a semiconductor chip (1), MO denotes a final stage amplifying transistor of a power amplifier (PA) 114 of the transmitter 11, 52 denotes an attenuator, and 53 denotes a matching circuit of the transmitting side as illustrated in FIG. 5.

In FIG. 16, the attenuator 52 is formed on the semiconductor chip 51, and the matching circuit 53 is externally provided, however, the attenuators 52 may be formed outside the semiconductor chip 51.

The attenuator 52 is formed as a π-type resistor network, and includes a resistor R52 which is provided in series between a drain of the transistor M0 and an output terminal OUT, and resistors R51 and R53 respectively provided between both ends of the resistor R52 and the ground (GND). Further, the attenuator 52 includes transistors (switching elements) M1 to M3.

An output signal Sin is input to a gate of the transistor M0, a source of the transistor M0 is connected to the ground (GND), and a drain of the transistor M0 is connected to an output terminal OUT of an LSI chip via the resistor R52.

The resistor R51 and the transistor M1 connected in series, and the resistor R53 and the transistor M3 connected in series are provided between both ends of the resistor R52 and the ground (GND). Further, a source and a drain of the transistor M2 which is connected in parallel with the resistor R52 are connected to the both ends of the resistor R52.

Note that, the transistors M1 to M3 are functioned as switches, and switching states of the transistors M1 to M3 are changed between the normal power transmission (compliant mode and low power mode: for example, at the time of −10 dBm transmission) and the low power transmission (high speed mode: for example, at the time of −50 dBm transmission).

Specifically, in the compliant mode and the low power mode, the transistor M2 is turned on and the transistors M1 and M3 are turned off, and conversely, in the high speed mode, the transistor M2 is turned off and the transistors M1 and M3 are turned on.

For example, by assuming that a transmission power of the compliant mode and the low power mode is at −10 dBm and a transmission power of the high speed mode is −50 dBm, in the high speed mode, an output power is decreased about 40 dB by the attenuator 52 of a π-type resistor network including three resistors R51 to R53.

Further, for example, in order to match input and output impedances of the attenuator 52 to 600 ohms, resistance values r51 to r53 of the resistors R51 to R53 are set as r51=r53=600 [Ω], and r52=30k [Ω].

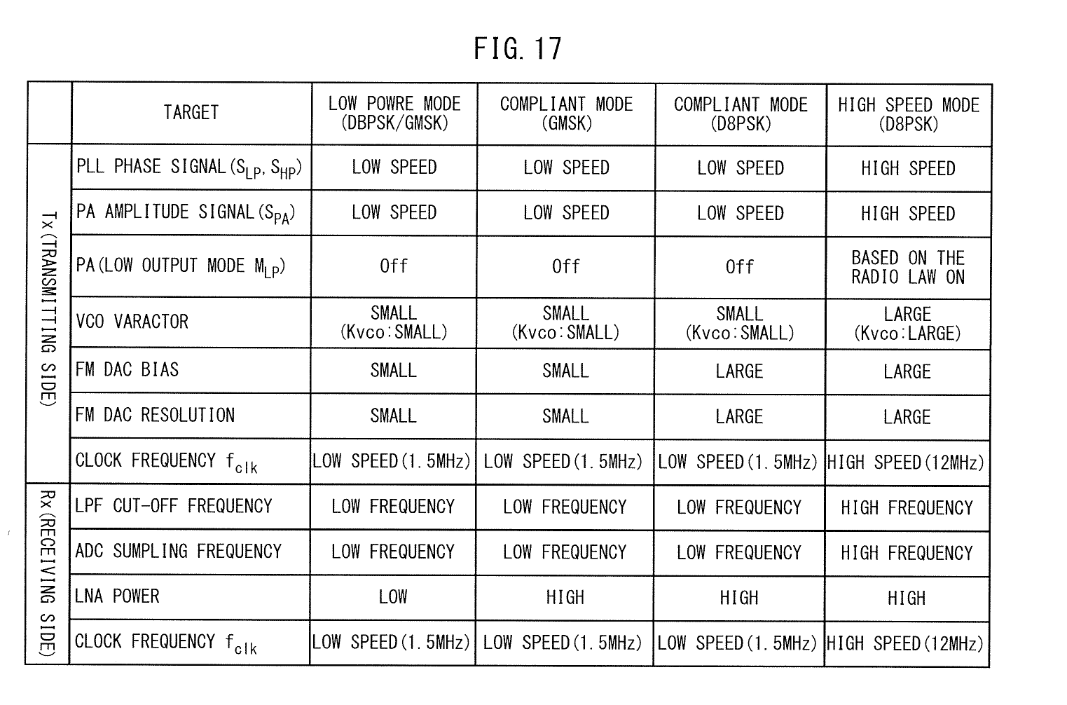

FIG. 17 is a diagram illustrating collectively the control signals in the embodiment described above. As illustrated in FIG. 17, according to the present embodiment, by controlling the receiving side and the transmitting side based on the low power mode, the compliant mode and the high speed mode, it may be possible to realize wide range data transfer rates.

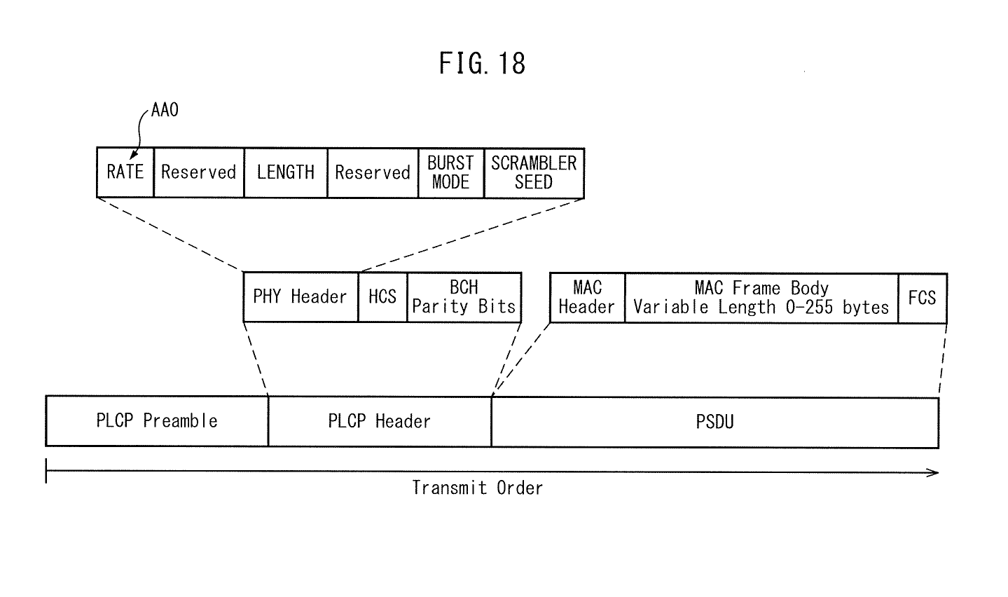

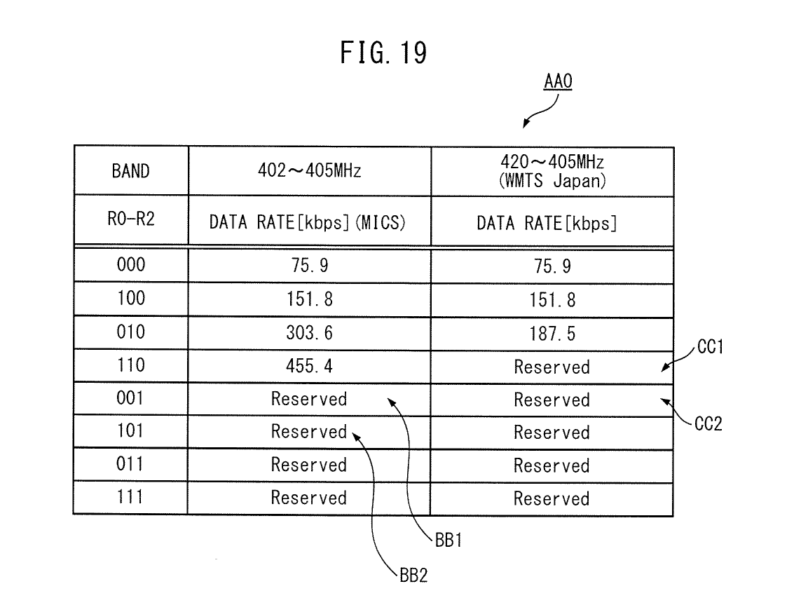

FIG. 18 is a diagram illustrating a standard IEEE802.15.6 compliant PPDU (Physical-layer Protocol Data Unit), and FIG. 19 is a diagram illustrating a data transfer rate that is set to a rate (RATE) field in IEEE802.15.6 compliant PPDU standard illustrated in FIG. 18. The standard IEEE802.15.6 compliant PPDU is illustrated in FIG. 18, wherein a data transfer rate set in a rate field (RATE) is determined as illustrated in FIG. 19.

Therefore, as illustrated in FIG. 19, the high speed mode (data rate (data transfer rate): 3600 kbps) and the low power mode (data rate: 9.487 (9.5) kbps) in each embodiment described above are determined by using a reserved (“Reserved”: retention) region.

Specifically, for the MICS using a frequency band of 402 MHz to 405 MHz, “3600” of the high speed mode is set to a region BB1 which is “Reserved,” and “9.487” of the low power mode is set to a region BB2 which is “Reserved”.

Further, for the WMTS using a frequency band of 420 MHz to 450 MHz, “3600” of the high speed mode is set to a region CC1 which is “Reserved,” and “9.487” of the low power mode is set to a region CC2 which is “Reserved”.

In the above descriptions, the embodiments are not limited to apply IEEE802.15.6 of 400 MHz band, but also may apply various frequency bands, and various standards (specifications) such as ZigBee (registered trademark) or Bluetooth (registered trademark) Low Energy (BLE).

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a illustrating of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A transmitter comprising:
a phase control circuit configured to receive a first modulation signal from a first path for modulating a first frequency signal, and a second modulation signal from a second path for modulating a second frequency signal higher than the first frequency; and
a power amplifier configured to receive a third modulation signal from a third path for controlling a gain, wherein
the phase control circuit includes:
a variable frequency divider, a frequency division ratio of the variable frequency divider being controlled by the first modulation signal;
a frequency modulation D/A converter configured to modulate the frequency by the second modulation signal; and
a voltage controlled oscillator, including a varactor, configured to receive a first control voltage based on the first modulation signal and a second control voltage based on the second modulation signal, wherein
at least one of a capacitance value of the varactor of the voltage controlled oscillator, a control bit number of the frequency modulation D/A converter, and a bias current value of the frequency modulation D/A converter is changed based on a data transfer rate.

2. The transmitter according to claim 1, wherein
when the data transfer rate is at a second data transfer rate higher than a first data transfer rate, the capacitance value of the varactor in the second data transfer rate is set larger than that in the first data transfer rate.

3. The transmitter according to claim 1, wherein
when the data transfer rate is at a second data transfer rate higher than a first data transfer rate, the control bit number of the frequency modulation D/A converter in the second data transfer rate is set larger than that in the first data transfer rate.

4. The transmitter according to claim 1, wherein
when the bias current value of the frequency modulation D/A converter is at a second data transfer rate higher than a first data transfer rate, the bias current value of the frequency modulation D/A converter in the second data transfer rate is set larger than that in the first data transfer rate.

5. The transmitter according to claim 1, wherein
when the bias current value of the frequency modulation D/A converter is at a second data transfer rate higher than a first data transfer rate, an output signal of the power amplifier in the first data transfer rate is attenuated than that in the first data transfer rate.

6. The transmitter according to claim 5, wherein the transmitter further comprises:
a sigma-delta modulator configured to receive the first modulation signal and perform sigma-delta modulation, wherein
a dividing ratio of the variable frequency divider is controlled based on an output signal of the sigma-delta modulator.

7. The transmitter according to claim 6, wherein the transmitter further comprises:
an amplitude modulation decoder configured to receive the third modulation signal, wherein
a gain of the power amplifier is controlled based on an output signal of the amplitude modulation decoder.

8. The transmitter according to claim 7, wherein the transmitter further comprises:
a phase frequency detector configured to receive an output signal of the variable frequency divider, detect a phase frequency, and control the first modulation signal which is input to the voltage controlled oscillator via a charge pump and a loop filter.

9. The transmitter according to claim 8, wherein
a clock signal input to the phase frequency detector, the sigma-delta modulator and the phase frequency detector is controlled in accordance with the data transfer rate.

10. A transceiver circuit comprising:
a transmitter; and
a receiver, wherein
the transmitter comprises:
a phase control circuit configured to receive a first modulation signal from a first path for modulating a first frequency signal, and a second modulation signal from a second path for modulating a second frequency signal higher than the first frequency; and
a power amplifier configured to receive a third modulation signal from a third path for controlling a gain, wherein
the phase control circuit includes:
a variable frequency divider, a frequency division ratio being controlled by the first modulation signal;
a frequency modulation D/A converter configured to modulate the frequency by the second modulation signal; and
a voltage controlled oscillator, including a varactor, configured to receive a first control voltage based on the first modulation signal and a second control voltage based on the second modulation signal, wherein
at least one of a capacitance value of the varactor of the voltage controlled oscillator, a control bit number of the frequency modulation D/A converter, and a bias current value of the frequency modulation D/A converter is changed based on a data transfer rate.

11. The transceiver circuit according to claim 10, wherein
the receiver comprises:
a low noise amplifier configured to amplify a received signal;
a mixer configured to mix an output signal of the low noise amplifier and a local frequency signal;
a variable cut-off frequency low pass filter configured to pass a low frequency band signal of an output signal of the mixer by changing a cut-off frequency of the variable cut-off frequency low pass filter; and
a variable sampling frequency A/D converter configured to A/D convert an output signal of the variable cut-off frequency low pass filter by changing a sampling frequency.

12. The transceiver circuit according to claim 10, wherein
the receiver comprises:
a variable power low noise amplifier configured to amplify a received signal by changing a power;
a mixer configured to mix an output signal of the variable power low noise amplifier and a local frequency signal;
a low pass filter configured to pass a low frequency band signal of an output signal of the mixer; and
an A/D converter configured to A/D convert an output signal of the low pass filter.

13. A wireless transmitting and receiving system comprising:
at least one node including a transceiver circuit; and
at least one hub including the transceiver circuit, which includes a transmitter and a receiver, wherein
the transmitter comprises:
a phase control circuit configured to receive a first modulation signal from a first path for modulating a first frequency signal, and a second modulation signal from a second path for modulating a second frequency signal higher than the first frequency; and
a power amplifier configured to receive a third modulation signal from a third path for controlling a gain, wherein
the phase control circuit includes:
a variable frequency divider, a frequency division ratio of the variable frequency divider being controlled by the first modulation signal;
a frequency modulation D/A converter configured to modulate the frequency by the second modulation signal; and
a voltage controlled oscillator, including a varactor, configured to receive a first control voltage based on the first modulation signal and a second control voltage based on the second modulation signal, wherein
at least one of a capacitance value of the varactor of the voltage controlled oscillator, a control bit number of the frequency modulation D/A converter, and a bias current value of the frequency modulation D/A converter is changed based on a data transfer rate.

14. The wireless transmitting and receiving system according to claim 13, wherein
the receiver comprises:
a variable power low noise amplifier configured to amplify a received signal by changing a power;
a mixer configured to mix an output signal of the variable power low noise amplifier and a local frequency signal;
a low pass filter configured to pass a low frequency band signal of an output signal of the mixer; and
an A/D converter configured to A/D convert an output signal of the low pass filter.

15. The wireless transmitting and receiving system according to claim 14, wherein
in the node and the hub,
the variable power low noise amplifier of the transceiver circuit in a signal receiving side sets a spreading factor of the variable power low noise amplifier to equal to or larger than two, when a power used to amplify the received signal by the variable power low noise amplifier is decreased.

16. The wireless transmitting and receiving system according to claim 14, wherein
in the node and the hub,
the variable power low noise amplifier of the transceiver circuit in a signal receiving side changes at least one of the control bit number of the frequency modulation D/A converter and the bias current value of the frequency modulation D/A converter, when a power used to amplify the received signal by the variable power low noise amplifier is decreased.
